(19) United States
(12) Patent Application Publication
(10) Pub. No.: US 2019/0249296 A1
(43) Pub. Date: Aug. 15, 2019

(54) METHOD FOR MANUFACTURING SILICON NITRIDE THIN FILM USING PLASMA ATOMIC LAYER DEPOSITION

(71) Applicant: DNF CO., LTD., Daejeon (KR)

(72) Inventors: Se Jin JANG, Jeju-si (KR); Sang-Do LEE, Daejeon (KR); Joong Jin PARK, Daejeon (KR); Sung Gi KIM, Daejeon (KR); Byeong-il YANG, Daejeon (KR); Gun-Joo PARK, Daejeon (KR); Jeong Joo PARK, Daejeon (KR); Jang Hyeon SEOK, Sejong (KR); Sang Ick LEE, Daejeon (KR); Myong Woon KIM, Daejeon (KR)

(21) Appl. No.: 16/319,452

(22) PCT Filed: Jul. 19, 2017
(86) PCT No.: PCT/KR2017/007764

§ 371 Date: Jan. 21, 2019

(30) Foreign Application Priority Data
Jul. 22, 2016 (KR) 10-2016-0093165
Jul. 18, 2017 (KR) 10-2017-0090707

(51) Int. Cl. C23C 16/34; C23C 16/455; H01L 21/02

(52) U.S. Cl. CPC C23C 16/345; C23C 16/45553; C23C 16/45536; C07F 7/21; H01L 21/02274; H01L 21/0217; H01L 21/0228

(57) ABSTRACT

The present invention relates to a method for manufacturing a high-purity silicon nitride thin film using plasma atomic layer deposition. More specifically, the present invention can realize improved thin film efficiency and a step coverage by performing a two-stage plasma excitation step and can provide a high-purity silicon nitride thin film with an improved deposition rate despite a low film-forming temperature.

### TECHNICAL FIELD

The present invention relates to a method for manufacturing a silicon nitride thin film using plasma atomic layer deposition, and more particularly, to a method for manufacturing a high-purity silicon nitride thin film using plasma atomic layer deposition method including a two-stage plasma excitation step.

### BACKGROUND ART

A silicon nitride thin film has high resistance to hydrogen fluoride (HF). Thus, in the manufacturing process of semiconductor devices such as a memory and a large scale integrated circuit (LSI), and the like, the silicon nitride thin film is utilized as an etching stopper layer at the time of etching a silicon oxide thin film (SiO₂), and the like, a film for preventing an increase in deviation of resistance value of a gate electrode, a film for preventing diffusion of a dopant, and the like.

In particular, in forming the silicon nitride thin film, it is required to lower a film-forming temperature. For example, when the silicon nitride thin film is formed by using a conventional low pressure chemical vapor deposition (LPCVD) method, the film-forming temperature reaching 760° C. is required. However, when the silicon nitride thin film is formed by an atomic layer deposition (ALD) method, it is possible to satisfy a film-forming temperature lower than the temperature described above.

In the ALD method, two kinds of (or more) raw material gases used for film formation under any film formation conditions (temperature, time, and the like) are alternately supplied one by one to the substrate and adsorbed by one atomic layer unit to perform film formation using a surface reaction. For example, a first source gas and a second source gas are allowed to alternately flow along a surface of an object to be treated so that source gas molecules in the first source gas are adsorbed on the surface of the object to be treated, and source gas molecules of the adsorbed first source gas are reacted with source gas molecules of the second raw material gas to form a film having a thickness of one molecular layer. Then, by repeating this step, it is possible to form a high-quality thin film on the surface of the object to be treated.

Japanese Patent Laid-Open Publication No. 2004-281853 discloses a method for forming a silicon nitride film by alternately supplying dichlorosilane (DCS: SiH₂Cl₂) and ammonia (NH₃) by the ALD method. Specifically, the above-described method is a method for forming a silicon nitride thin film at a low temperature of 300° C. to 600° C. by supplying an ammonia radical (NH₃⁺) in which ammonia is activated by a plasma. However, the silicon nitride thin film formed by the above-described method has disadvantages in that a wet etch rate is large due to an increase in concentration of chlorine (Cl), which is a cause of lowering resistance to hydrogen fluoride, and an etch selectivity (selection ratio) to an oxide film is small.

In order to improve resistance to hydrogen fluoride of the above-described silicon nitride thin film, it is possible to consider a method for introducing carbon atoms (C) into the silicon nitride thin film. However, introduction of the carbon atoms into the silicon nitride thin film at a low temperature region of 400° C. or less is a factor of structural defects and may cause deterioration of insulation resistance.

Korean Patent Registration No. 0944842 discloses a technique for forming a silicon nitride thin film having a high stress at a low temperature (390° C. to 410° C.) by the ALD method. However, this technique has a disadvantage in that chlorine atoms (Cl), which are unnecessary atoms contained in a chemical ligand, remain in the thin film to induce particles on a surface of a substrate, and thus it is difficult to form a good film quality.

U.S. Patent Publication No. 2013-183835 discloses a method for forming a silicon nitride thin film with a high stress at a low temperature and an apparatus thereof. However, there are disadvantages in that since a high-power plasma is used, decomposition of a precursor including silicon is induced and impurities caused thereby are included, and thus it is difficult to form a good film quality.

Therefore, it is required to develop an alternative technique for solving the problems of the conventional ALD method for forming a silicon nitride thin film.

The present applicant confirmed that by performing a two-stage plasma excitation step using an organic silicon precursor including a silicon-nitrogen bond (Si—N bond), a high purity silicon nitride thin film was capable of being provided by solving problems of the conventional ALD method having the low film-forming temperature such as a low stress intensity, a high wet etch rate, and a low step coverage of the thin film while simultaneously having improved productivity, and completed the present invention.

### DISCLOSURE

### Technical Problem

An object of the present invention is to provide a method for manufacturing a high-purity silicon nitride thin film capable of stably maintaining good film quality characteristics.

Another object of the present invention is to provide a silicon nitride thin film having an improved wet etch rate and an improved step coverage by minimizing a content of impurities.

In one general aspect, a method for manufacturing a silicon nitride thin film including a two-stage plasma excitation step.

The method for manufacturing a silicon nitride thin film according to an embodiment of the present invention may be achieved by performing a unit cycle at least once, the unit cycle including: adsorbing an organic silicon precursor including a silicon-nitrogen bond on a substrate; and exciting a first plasma while injecting a first reaction gas and then exciting a second plasma while injecting a second reaction gas to provide one or more reactive sites.

The first reaction gas may be a mixture of a nitrogen gas and a hydrogenation gas.

The hydrogenation gas is not limited as long as it is a hydrogen gas (H₂) or a reaction gas simultaneously including a nitrogen atom (N) and a hydrogen atom (H), but may be preferably one or two selected from the group consisting of hydrogen (H₂) or ammonia (NH₃), hydrazine (N₂H₄), and the like.

The first reaction gas may be a mixture of the nitrogen gas and the hydrogenation gas at a flow ratio of 300:1 to 1:1. Here, it is preferable to inject the reaction gas mixed at the flow ratio described above into the apparatus. However, in an embodiment of the present invention, each of the nitrogen gas and the hydrogenation gas with a flow amount satisfying the flow ratio described above may be simultaneously injected into the apparatus.

The second reaction gas may be a reaction gas including nitrogen atoms (N) but not including hydrogen atoms (H), preferably a nitrogen gas.

The first plasma and the second plasma may be excited with a power of 500 W or less.

A temperature of the substrate may range from 50° C. to 400° C.

The organic silicon precursor including a silicon-nitrogen bond may be one or two or more selected from compounds represented by Chemical Formulas 1, 2, and 3 below:

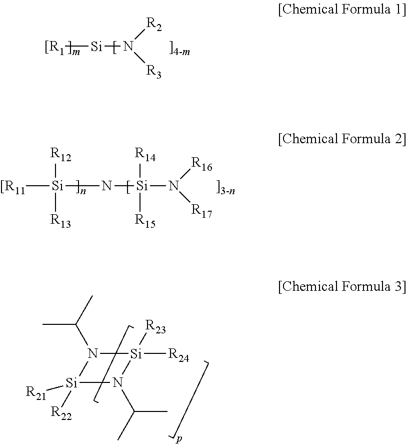

in Chemical Formulas 1, 2, and 3,

R₁ to R₃, R₁₁ to R₁₇, and R₂₁ to R₂₄ are each independently hydrogen, (C1-C5)alkyl, or (C2-C5)alkenyl;

n and m are each independently an integer of 0 to 3, and

p is an integer of 1 to 3.

In another general aspect, there is provided a silicon nitride thin film in which an oxygen element content is 10 atom % or less based on total atoms present in the silicon nitride film, and a silicon-nitrogen/silicon-hydrogen area ratio (Si—N/Si—H) is 90 or more.

The silicon nitride thin film may have a step coverage of 80% or more.

### Advantageous Effects

According to the present invention, it is possible to form a stable silicon nitride thin film with a more improved deposition rate by using a two-stage plasma excitation step. Further, it is possible to provide a silicon nitride thin film including a high-quality Si—N bond at a lower film-forming temperature condition by introducing an organic silicon precursor having a predetermined Si—N bond.

According to the present invention, it is possible to minimize impurities in the silicon nitride film as well as to implement an excellent thin film efficiency by controlling a plasma excitation condition despite the lower film-forming temperature condition. In particular, a content of oxygen atoms in the silicon nitride thin film may be remarkably lowered by suppressing oxidation by atmospheric exposure after the process.

In summary, according to the present invention, the silicon nitride thin film satisfying a desired silicon-nitrogen bond absorption area ratio (based on a silicon-hydrogen bond) may be provided with high productivity by appropriately controlling each kind of reaction gas and a flow amount thereof in the plasma excitation step and repeatedly performing a unit cycle. Further, the silicon nitride thin film according to the present invention may have an excellent step coverage, and thus a fine pattern having an atomic layer thickness may be very uniformly formed and an improved wet etch rate (etch resistance) may be implemented.

### DESCRIPTION OF DRAWINGS

FIG. 1 illustrates a method for depositing a silicon nitride thin film according to the present invention.

FIG. 2 shows results of infrared spectroscopic analysis of silicon nitride thin films manufactured in Examples 1 to 8.

FIG. 3 shows results of infrared spectroscopic analysis of silicon nitride thin films manufactured in Example 9 and Comparative Examples 1 to 6.

FIG. 4 illustrates results of transmission electron microscopic analysis of silicon nitride thin films manufactured in Example 1, Example 3, Example 7, Comparative Example 1, Comparative Example 2, and Comparative Example 6.

FIG. 5 shows evaluation of etch characteristics with respect to hydrogen fluoride of the silicon nitride thin films manufactured in Example 3 and Comparative Example 2, and results of transmission electron microscopic analysis of change in thickness before and after etching.

FIG. 6 illustrates results of composition analysis of the silicon nitride thin films manufactured in Example 3, Example 5, Comparative Example 2, and Comparative Example 4.

### BEST MODE

Hereinafter, a method for manufacturing a silicon nitride thin film using plasma atomic layer deposition according to the present invention is described. Unless otherwise defined, the technical terms and scientific terms used herein have meanings generally understood by those skilled in the art to which the present invention pertains. Known functions and constitutions that may obscure the gist of the present invention with unnecessary detail will be omitted.

The term “silicon nitride thin film” in the present invention means to be manufactured by repeating a unit cycle described below according to the present invention, and it is possible to control desired physical properties (for example, stress intensity, wet etch rate, step coverage, and the like) of the silicon nitride thin film by process conditions of each unit cycle, the number of repetition times, and the like. Further, the term “atomic layer” in the present invention means a unit layer constituting the silicon nitride thin film.

According to the present invention, it is possible to provide a silicon nitride thin film including a high level of silicon-nitrogen bond by performing a two-stage plasma excitation step using an organic silicon precursor having a predetermined silicon-nitrogen bond (Si—N bond) without including halogen. Thus, according to the present invention, it is possible to provide a silicon nitride thin film having further improved stress intensity.

In addition, according to the present invention, a high-quality silicon nitride thin film may be stably provided by suppressing oxidation due to atmospheric exposure after the process despite low film-forming temperature condition to significantly reduce an oxygen element content in the thin film.

Due to process characteristics according to the present invention, a content of impurities in the silicon nitride film may be minimized and an atomic layer formed by the unit cycle may effectively adsorb the subsequent organic silicon precursor including a silicon-nitrogen bond.

In other words, according to the present invention, the atomic layer formed by the unit cycle provides one or more reactive sites that are capable of forming a strong bond with the subsequent organic silicon precursor including a silicon-nitrogen bond, thereby implementing a more improved deposition rate and enabling excellent physical properties of the silicon nitride thin film. In effects described above, the present invention has remarkable effects as compared to a plasma enhanced atomic layer deposition method including a one-stage plasma excitation step.

The unit cycle of the method for manufacturing a silicon nitride thin film by the plasma enhanced atomic layer deposition method according to an embodiment of the present invention is characterized by including a two-stage plasma excitation step.

Specifically, the method for manufacturing a silicon nitride thin film using plasma enhanced atomic layer deposition according to an embodiment of the present invention includes adsorbing an organic silicon precursor including a silicon-nitrogen bond on a substrate; and exciting a first plasma while injecting a first reaction gas and then exciting a second plasma while injecting a second reaction gas to provide one or more reactive sites.

In the method for manufacturing a silicon nitride thin film by plasma enhanced atomic layer deposition according to an embodiment of the present invention, the adsorbing of the organic silicon precursor may be performed at a film-forming temperature ranging from 50° C. to 400° C.

As a specific example, the adsorbing of the organic silicon precursor may be performed at a film-forming temperature ranging from 50° C. to 350° C.

In the method for manufacturing a silicon nitride thin film by plasma enhanced atomic layer deposition according to an embodiment of the present invention, in the adsorbing of the organic silicon precursor, a plasma power of the subsequent two-stage at the film-forming temperature of 350° C. or less may be suitably controlled in order to implement stress intensity of an improved thin film.

As a specific example, the step of adsorbing the organic silicon precursor may be performed under a vapor pressure of 0.1 to 100 torr, preferably 0.1 to 80 torr, and more preferably 1 to 50 torr.

The substrate according to an embodiment of the present invention is not limited as long as it is a substrate used in a conventional plasma enhanced atomic layer deposition. Non-limiting example thereof may include a semiconductor substrate, a conductive substrate, an insulating substrate, and the like. Further, the substrate may be formed with an arbitrary pattern or layer.

The organic silicon precursor including a silicon-nitrogen bond according to an embodiment of the present invention is not limited as long as the organic silicon precursor includes a silicon-nitrogen bond, but is preferably selected from Chemical Formulas 1, 2, and 3 below:

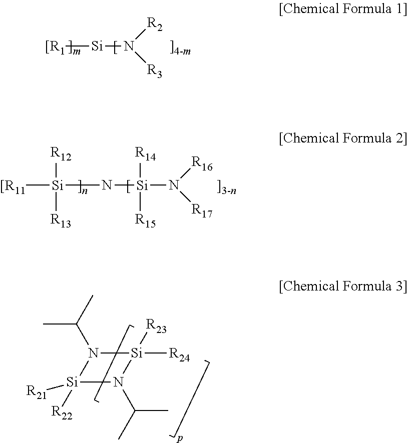

in Chemical Formulas 1, 2, and 3,

R₁ to R₃, R₁₁ to R₁₇, and R₂₁ to R₂₄ are each independently hydrogen, (C1-C5)alkyl, or (C2-C5)alkenyl;

n and m are each independently an integer of 0 to 3, and

p is an integer of 1 to 3.

The organic silicon precursor including a silicon-nitrogen bond may have excellent volatility and high reactivity even at room temperature (23° C.) to 40° C. and under atmospheric pressure, and thus it is possible to implement high thermal stability and stress intensity of the thin film as well as to implement a high deposition rate by the plasma enhanced atomic layer deposition despite the film-forming temperature of 400° C. or less.

In particular, the organic silicon precursor according to the present invention exhibits a strong binding force with the atomic layer formed by the unit cycle including the two-stage plasma excitation step to implement a remarkably improved step coverage. It is expected that this effect is derived by performing a sequential plasma generation step according to the present invention described above.

In the above-described effects, more preferably, the organic silicon precursor including a silicon-nitrogen bond may be selected from the following structures, but is not limited thereto:

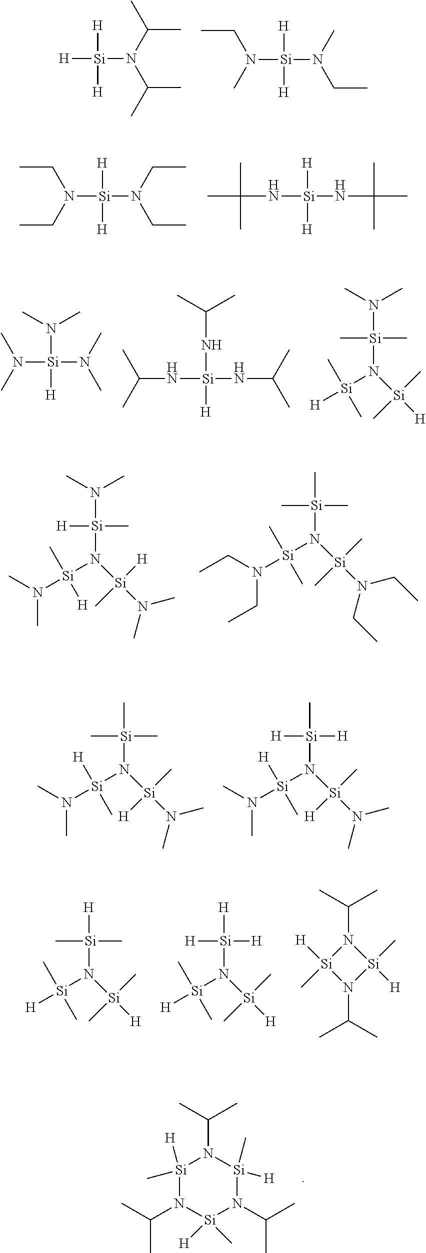

In the adsorbing of the organic silicon precursor, the organic silicon precursor may be injected for 1 to 90 seconds. In view of stable atomic layer formation, the organic silicon precursor may be injected for preferably 1 to 60 seconds, and more preferably for 3 to 30 seconds.

In addition, according to an embodiment of the present invention, the method may further include, after the adsorbing of the organic silicon precursor, purging.

The purging may be performed by using one or more purge gases selected from nitrogen gas, argon gas, helium gas, neon gas, and the like.

As a specific example, the purging may be performed by injecting the purge gas at a flow amount ranging from 1 to 10,000 sccm (square cubic centimeters) for 1 to 1,000 seconds to remove organic silicon precursors and any impurities, and the like, that are not adsorbed but remain in the apparatus.

In the method for manufacturing a silicon nitride thin film using plasma atomic layer deposition according to an embodiment of the present invention, the exciting of a first plasma may excite a plasma under the first reaction gas, and thus the organic silicon precursor including the silicon-nitrogen bond is reacted with a portion or all of the layer in which the organic silicon precursor is chemisorbed (also referred to as being a chemisorbed layer), thereby serving to form the atomic layer including the silicon-nitrogen bond and to fix the formed atomic layer.

The exciting of a first plasma according to an embodiment of the present invention is performed under a first reaction gas in which a nitrogen gas (N₂) and a hydrogen gas are mixed. This step imparts properties that make binding with the subsequent organic silicon precursor easy.

As a specific example, the first reaction gas may be injected at a flow amount ranging from 1,000 to 100,000 sccm (square cubic centimeters), preferably at a flow amount ranging from 3,000 to 50,000 sccm, and more preferably 5,000 to 10,000 sccm.

The exciting of the first plasma according to an embodiment of the present invention may excite the first plasma under the first reaction gas mixed with the above-described composition, thereby improving the area ratio of the silicon-nitrogen bond in the finally formed silicon nitride thin film and exhibiting remarkable effects as compared to an example using a single reaction gas in the above-described effects.

Further, by exciting the plasma under the first reaction gas, the organic silicon precursor may react with the chemisorbed layer to form the atomic layer while simultaneously removing impurities generated after the reaction by hydrogenation.

Here, the hydrogenation gas is not limited as long as it is a hydrogen gas or a reaction gas including nitrogen atoms (N) and hydrogen atoms (H) at the same time. Non-limiting examples of the hydrogenation gas may include hydrogen (H₂), ammonia (NH₃), hydrazine (N₂H₄), and the like.

The exciting of the first plasma according to the present invention may be performed under the first reaction gas in which the nitrogen gas and the hydrogen gas are mixed at a flow ratio of 300:1 to 1:1. When the above-described flow ratio is satisfied, it is possible to implement excellent step coverage at an improved deposition rate. In implementing the above-described effects, the flow ratio may preferably be 250:1 to 20:1, and more preferably 200:1 to 50:1.

Further, according to the present invention, it is preferable to inject the reaction gas mixed at the flow ratio described above into the apparatus. However, in an embodiment of the present invention, each of the nitrogen gas and the hydrogenation gas with a flow amount satisfying the flow ratio described above may be simultaneously injected into the apparatus.

When the exciting of the first plasma according to the present invention described above is performed under the first reaction gas in which the nitrogen gas and the hydrogen gas are mixed, the effect induced in the exciting of the first plasma according to the present invention described above may be synergistic as compared to effects obtained under a single reaction gas. Particularly, when only the hydrogenation gas is employed as the reaction gas, it is not preferable since impurities are formed due to excessive hydrogen atoms, or the like, induced by the plasma.

The exciting of the first plasma according to an embodiment of the present invention may be performed at a film-forming temperature ranging from 50° C. to 400° C. The film-forming temperature may be interpreted to have the same meaning as a substrate temperature of the present invention. In order to control physical properties of the silicon nitride thin film, it is possible to appropriately control the film-forming temperature, the pressure, and the power of the power source applied to generate the plasma, and the like.

As a specific example, the first plasma may be excited with a power of 500 W or less at the film-forming temperature in the above-described range.

As a specific example, the first plasma may be excited with a power ranging from 150 W to 500 W at the film-forming temperature ranging from 50° C. to 200° C.

As a specific example, the first plasma may be excited with a power ranging from 50 W to less than 150 W at the film-forming temperature of more than 200° C.

In the exciting of the first plasma according to an embodiment of the present invention, the first plasma may be irradiated for 1 to 120 seconds, preferably 1 to 90 seconds, and more preferably 3 to 60 seconds in view of minimization of impurities.

Further, the method may further include, after the exciting of the first plasma according to an embodiment of the present invention, purging.

In the purging, the first reaction gas may be used or one or more purge gases selected from nitrogen gas, argon gas, helium gas, neon gas, and the like may be used.

As a specific example, the purging may be performed by injecting the purge gas at a flow amount ranging from 1 to 10,000 sccm (square cubic centimeters) for 1 to 1,000 seconds to remove non-reacted organic silicon precursors and any impurities, and the like, that may remain in the apparatus.

In the method for manufacturing a silicon nitride thin film by plasma enhanced atomic layer deposition according to an embodiment of the present invention, the exciting of the second plasma may serve to generate a plasma under the second reaction gas to remove impurities in the atomic layer of the silicon-nitrogen bond formed in the exciting of the first plasma, and to form one or more reactive sites so as to implement improved adsorption force with a layer in which the organic silicon precursor is chemisorbed (also referred to as being a chemisorbed layer). Here, the second reaction gas may be a reaction gas including nitrogen atoms (N) but not including hydrogen atoms (H), preferably nitrogen gas.

By performing the two-stage plasma excitation step according to the present invention, the impurities bond remaining in the atomic layer may be substituted with nitrogen, thereby satisfying a higher silicon-nitrogen bond absorption area ratio (based on a silicon-hydrogen bond) while simultaneously remarkably improving an adsorption force with the subsequent organic silicon precursor. In particular, it is preferable since a content (atom %) of oxygen atoms in the atomic layer may be minimized.

As a specific example, the second reaction gas may be injected at a flow amount ranging from 1,000 to 100,000 sccm (square cubic centimeters), preferably at a flow amount ranging from 3,000 to 50,000 sccm, and more preferably 5,000 to 10,000 sccm.

In a specific example, the second plasma may be excited with a power of 500 W or less, preferably a power ranging from 50 to 400 W, and more preferably from 50 to 200 W.

In the exciting of the second plasma according to an embodiment of the present invention, the second plasma may be irradiated for 1 to 200 seconds, preferably 10 to 120 seconds, and more preferably 30 to 90 seconds in view of minimization of impurities.

Further, the method may further include, after the exciting of the second plasma according to an embodiment of the present invention, purging.

In the purging, the second reaction gas may be used or one or more purge gases selected from argon gas, helium gas, neon gas, and the like may be used.

As a specific example, in the purging, the second reaction gas or the purge gas may be injected at a flow amount ranging from 1 to 10,000 sccm (square cubic centimeters) for 1 to 1,000 seconds to effectively remove any impurities, particularly, hydrogen atoms.

The unit cycle of the method for manufacturing a silicon nitride thin film by plasma enhanced atomic layer deposition according to an embodiment of the present invention may be performed to excite a two-stage plasma using the reaction gas satisfying a predetermined composition described above, thereby providing a high-purity silicon nitride thin film despite a low film-forming temperature. Further, the silicon nitride thin film according to the present invention may include the strongly bonded silicon-nitrogen bond to remarkably improve etching properties (for example, wet etch rate) and step coverage, which are physical properties, as well as high stress intensity.

Here, the etch characteristics may be resistant to a conventional cleaning liquid or an oxidation etchant. Non-limiting examples of the cleaning liquid or the oxidation etchant may include hydrogen peroxide (H₂O₂), ammonium hydroxide (NH₄OH), aqueous H₃PO₄ solution, aqueous hydrogen fluoride (HF) solution, and buffered oxide etch (BOE) solution, and the like, but the cleaning liquid is not limited thereto. However, the silicon nitride thin film according to the present invention has excellent resistance to the aqueous HF solution, and thus the etch resistance as referred to in the present invention may be resistant to the aqueous HF solution or a buffered oxide etch (BOE) solution, but is not limited thereto.

Further, the method for manufacturing a silicon nitride thin film by plasma enhanced atomic layer deposition according to an embodiment of the present invention may be changed, for example, the composition of the organic silicon precursor, the reaction gas, and the like, may be changed and time for supplying the organic silicon precursor, the reaction gas, and the like may be changed within the above-described range.

Hereinafter, a silicon nitride thin film manufactured through the method for manufacturing a silicon nitride thin film by plasma enhanced atomic layer deposition according to an embodiment of the present invention will be described.

The silicon nitride thin film according to an embodiment of the present invention is formed by depositing an atomic layer including silicon-nitrogen bonds with an excellent binding force, which is a high-purity silicon nitride thin film having minimized impurities such as oxygen atoms, hydrogen atoms, carbon atoms, and the like.

In particular, the silicon nitride thin film may have an oxygen element content of 10 atom % or less based on total atoms present in the silicon nitride film, and may have a silicon-nitrogen/silicon-hydrogen area ratio (Si—N/Si—H) of 90 or more.

As a specific example, the silicon nitride film may preferably have the oxygen element content ranging from 0.1 to 10 atom % and preferably have the silicon-nitrogen/silicon-hydrogen area ratio (Si—N/Si—H) ranging from, preferably, 100 to 400.

In one embodiment, the silicon nitride thin film may be a high purity silicon nitride thin film having a silicon/nitrogen atomic composition ratio (Si/N) ranging from 0.70 to 0.89.

As a specific example, the silicon nitride thin film may have a hydrogen atom content ranging from 0.1 to 30 atom %, and a carbon atom content ranging from 0 to 0.5 atom %.

According to the present invention, it is possible to provide the silicon nitride thin film having a step coverage of 80% or more by performing the two-stage plasma excitation step using the reaction gas satisfying the predetermined composition. In other words, it may be appreciated that the silicon nitride thin film according to the present invention does not cause adsorption failure or adsorption disturbance of the organic silicon precursor in the process.

The step coverage of the silicon nitride thin film according to an embodiment of the present invention may be preferably 80 to 120%, more preferably 90 to 100%, but is not limited thereto.

Further, the silicon nitride thin film according to an embodiment of the present invention has improved etching characteristics.

Hereinafter, the present invention is described in more detail with reference to the following Examples. However, these Examples are provided for assisting in the understanding of the present invention, and the scope of the present invention is not limited to these Examples in any sense.

Further, all Examples below were performed using a known plasma enhanced atomic layer deposition (PEALD) method using a commercially available showerhead type 200 mm single wafer type ALD apparatus. The thickness of the deposited silicon nitride thin film was measured by using an ellipsometer (M2000D, Woollam) and a transmission electron microscope (TEM), and the composition thereof was analyzed by using an infrared spectroscopy (IFS66V/S & Hyperion 3000, Bruker Optiks), an Auger electron spectroscopy (AES, Microlab 350, Thermo Electron), and a secondary ion mass spectrometer (SIMS).

### Example 1

In a conventional plasma enhanced atomic layer deposition (PEALD) apparatus using plasma enhanced atomic layer deposition (PEALD), bis(dimethylaminomethylsilyl)trimethylsilylamine heated to 94° C. was injected for 15 seconds at a flow amount (50 sccm) of nitrogen (N₂) and adsorbed onto a silicon (Si) wafer substrate, thereby forming a chemisorbed layer, and then nitrogen (N₂) was injected at a flow amount of 6000 sccm for 32 seconds, followed by purging. A plasma excited with 75 W of power was generated by injecting a mixed gas of nitrogen (N₂) and ammonia (NH₃) at a flow ratio of 120:1 (sccm: sccm) into the substrate for 30 seconds and was reacted with the chemisorbed layer, and nitrogen (N₂) was injected at a flow amount of 6000 sccm for 10 seconds to perform purging. A plasma excited with 75 W of power was generated by injecting nitrogen (N₂) at a flow amount of 6000 sccm into the substrate for 60 seconds to form one or more reactive sites, and then nitrogen (N₂) was injected at a flow amount of 6000 sccm for 20 seconds to perform purging.

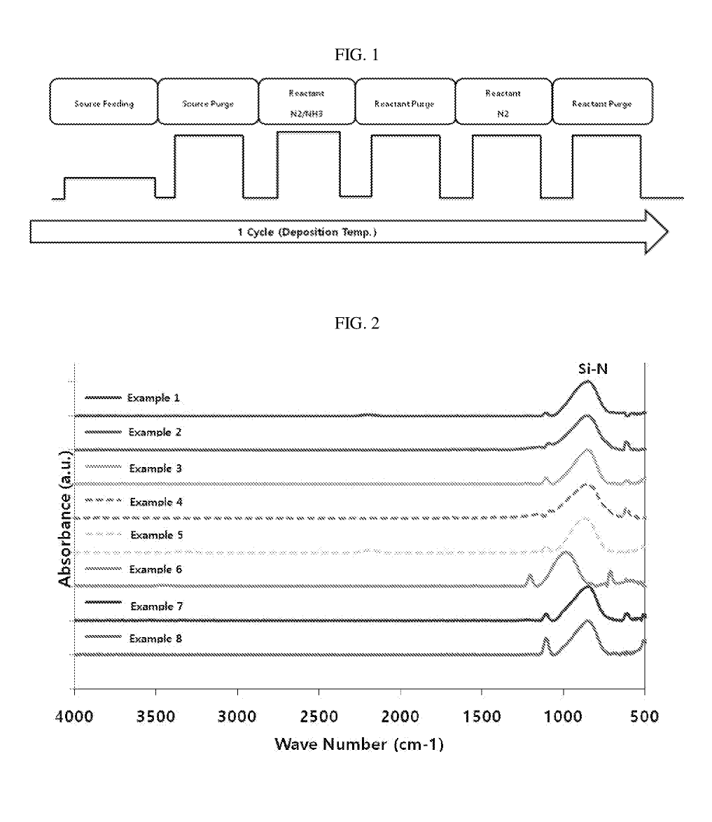

A silicon nitride thin film was manufactured by repeating the above-described method 240 times as a unit cycle. Hereinafter, specific deposition conditions are shown in FIG. 1 and Table 1 below.

### Examples 2 to 9

A silicon nitride thin film was manufactured in the same manner as in Example 1 except for repeating the unit cycle 240 times according to the specific deposition conditions shown in Table 1 below.

In order to confirm physical properties of the silicon nitride thin film manufactured by the above-described method, the thickness was measured through an ellipsometer and a transmission electron microscope, and molecular vibrations of Si—N bonds and Si—H bonds were observed using an infrared spectroscopy. Then, the area ratio thereof was compared. Further, the ratio of the silicon atoms and nitrogen atoms in the silicon nitride thin film and the element composition thereof were confirmed by using an Auger electron spectroscopy, and amounts of impurities (oxygen, carbon, hydrogen, and the like) in the silicon nitride thin film were expressed as atom % using a secondary ion mass spectrometry. Further, the etch resistance to hydrogen fluoride was compared with etch resistance (0.009 Å/sec) of a silicon nitride thin film formed by using bis(dimethylaminomethylsilyl)trimethylsilylamine and ammonia at 770° C. using low pressure chemical vapor deposition (LPCVD).

Physical properties of the silicon nitride thin film confirmed by the above-described method are shown in Tables 3 to 4 below, and FIGS. 2, 4 to 6.

TABLE 1

| | | Example | | | | | | | | |
|---|---|---|---|---|---|---|---|---|---|---|
| | | 1 | 2 | 3 | 4 | 5 | 6 | 7 | 8 | 9 |
| Substrate temperature (° C.) | | 350 | 350 | 350 | 350 | 100 | 100 | 350 | 350 | 350 |
| Precursor | Organic silicon precursor | A-1 | A-1 | A-2 | A-2 | A-2 | A-2 | A-3 | A-4 | A-1 |
| injection | Heating temperature (° C.) | 94 | 94 | 60 | 60 | 60 | 60 | 20 | 70 | 94 |
| conditions | Vapor pressure (torr) | 4.04 | 4.04 | 4.00 | 4.00 | 4.00 | 4.00 | 4.00 | 30.9 | 4.04 |
| | Injection time (sec) | 15 | 5 | 5 | 5 | 5 | 5 | 15 | 2 | 15 |
| First | Nitrogen injection | 6000 | 6000 | 6000 | 4000 | 6000 | 6000 | 6000 | 6000 | 6000 |
| plasma | amount (sccm) | | | | | | | | | |
| generation | Ammonia injection | 50 | 50 | 50 | 50 | 50 | 50 | 50 | 50 | 0 |
| conditions | amount (sccm) | | | | | | | | | |
| | Power (W) | 75 | 75 | 75 | 75 | 200 | 400 | 75 | 75 | 75 |
| | Time (sec) | 30 | 7 | 30 | 30 | 8 | 5 | 30 | 30 | 30 |
| Second | Nitrogen injection | 6000 | 6000 | 6000 | 6000 | 6000 | 6000 | 6000 | 6000 | 6000 |
| plasma | amount (sccm) | | | | | | | | | |
| generation | Ammonia injection | 0 | 0 | 0 | 0 | 0 | 0 | 0 | 0 | 50 |
| conditions | amount (sccm) | | | | | | | | | |
| | Power (W) | 75 | 75 | 75 | 75 | 200 | 400 | 75 | 75 | 75 |
| | Time (sec) | 60 | 15 | 60 | 60 | 60 | 60 | 60 | 60 | 60 |

*A-1: Bis(dimethylaminomethylsilyl)trimethylsilylamine
*A-2: 1,3-Diisopropyl-2,4-dimethyl cyclodisilazane
*A-3: Bis(dimethylaminomethylsilyl)trimethylsilylamine
*A-4: Bis(diethylamino)silane

### Comparative Examples 1 to 6

Silicon nitride thin films were manufactured by using a silicon (Si) wafer substrate in a conventional plasma enhanced atomic layer deposition (PEALD) apparatus using plasma enhanced atomic layer deposition (PEALD) and repeating a unit cycle 240 times, the unit cycle satisfying deposition conditions shown in Table 2 below.

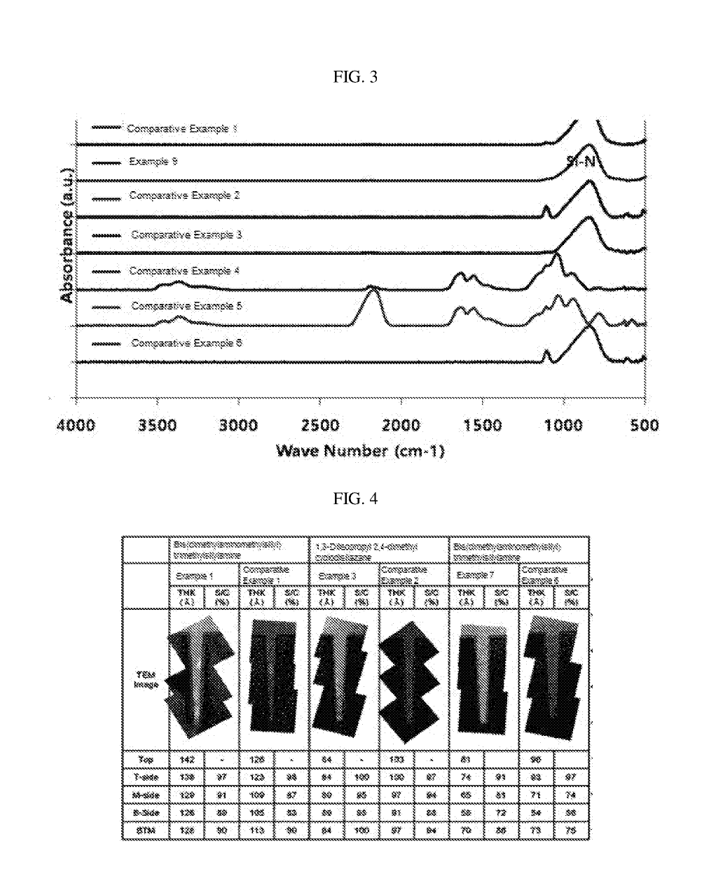

Physical properties of the silicon nitride thin films manufactured by the above method were confirmed by the method of Example 1, and results thereof are shown in Tables 3 to 4 below and FIGS. 3 to 6.

TABLE 2

| | | Comparative Example | | | | | |
|---|---|---|---|---|---|---|---|
| | | 1 | 2 | 3 | 4 | 5 | 6 |
| Substrate temperature (° C.) | | 350 | 350 | 350 | 100 | 100 | 350 |
| Precursor injection | Organic silicon precursor | A-1 | A-2 | A-2 | A-2 | A-2 | A-3 |
| conditions | Heating temperature (° C.) | 94 | 60 | 60 | 60 | 60 | 20 |
| | Vapor pressure (torr) | 4.04 | 4.00 | 4.00 | 4.00 | 4.00 | 4.00 |
| | Injection time (sec) | 15 | 5 | 5 | 5 | 5 | 15 |
| First plasma | Nitrogen injection | 6000 | 6000 | 4000 | 6000 | 6000 | 6000 |
| generation | amount (sccm) | | | | | | |
| conditions | Ammonia injection | 0 | 0 | 0 | 0 | 0 | 0 |
| | amount (sccm) | | | | | | |
| | Power (W) | 75 | 75 | 75 | 200 | 400 | 75 |
| | Time (sec) | 60 | 60 | 60 | 5 | 5 | 30 |

*A-1: Bis(dimethylaminomethylsilyl)trimethylsilylamine
*A-2: 1,3-Diisopropyl-2,4-dimethyl cyclodisilazane
*A-3: Bis(dimethylaminomethylsilyl)trimethylsilylamine

TABLE 3

| | | | Thin film | | |
|---|---|---|---|---|---|
| | | Wet etch | efficiency | | |
| | Deposition | ratio | (Deposition rate/ | IR | |
| | rate | (vs. LPCVD | Wet etch ratio * | | Si—N/Si—H |
| | (\acute{Å}/cycle) | Si—N 0.009 \acute{Å}/sec) | 100, %) | Si—N (cm⁻¹) | area ratio |
| Example 1 | 0.52 | 0.6 | 86.7 | 849 | 333 |
| Example 2 | 0.42 | 0.7 | 60.0 | 839 | 100 |
| Example 3 | 0.35 | *2.0 | 17.5 | 858 | 143 |
| Example 4 | 0.28 | 0.5 | 56.0 | 852 | 143 |
| Example 5 | 0.4 | 5.76 | 6.9 | 851 | 130 |
| Example 6 | 0.4 | 5.61 | 7.1 | 870 | 116 |
| Example 7 | 0.31 | 0.45 | 68.9 | 850 | 143 |
| Example 8 | 0.3 | 0.5 | 60.0 | 849 | 125 |
| Example 9 | 0.28 | 0.5 | 56.0 | 854 | 83 |
| Comparative | 0.56 | 0.7 | 80.0 | 847 | 67 |
| Example 1 | | | | | |
| Comparative | 0.43 | *7.5 | 5.7 | 841 | 77 |
| Example 2 | | | | | |
| Comparative | 0.46 | 0.9 | 51.1 | 847 | 71 |
| Example 3 | | | | | |
| Comparative | 0.79 | 26.55 | 3.0 | — | — |
| Example 4 | | | | | |
| Comparative | 0.81 | 27.39 | 3.0 | — | — |
| Example 5 | | | | | |
| Comparative | 0.45 | 0.78 | 57.7 | 847 | 134 |
| Example 6 | | | | | |

Resistance to hydrogen fluoride of the silicon nitride thin film was a value obtained by immersing a 300:1 BOE solution (a mixture of 1 volume part of 49 wt % of hydrogen fluoride in water and 10 volume parts of 40 wt % of ammonium fluoride in the aqueous solution as a product manufactured by Dongjin Semichem Co., Ltd.) for 20 minutes, and measuring a change in thickness using an ellipsometer.
*indicates a wet etch rate result obtained by measuring a side bottom part using TEM after deposition on the patterned wafer.

As shown in Table 3, it was confirmed that Examples according to the present invention had excellent deposition rate and excellent etch resistance, thereby obtaining remarkable thin film efficiency. Further, it was confirmed that the thin film manufactured therefrom included a high level of silicon-nitrogen bond.

In other words, according to the present invention, it was confirmed that by performing the two-stage plasma excitation step, the silicon nitride thin film having improved film quality characteristics could be provided with more advantageous productivity.

TABLE 4

| | | Step Coverage (%) | | | |
|---|---|---|---|---|---|
| | Top | Side | | | |
| | Thickness (Å) | Top | Middle | Bottom | Bottom |
| Example 1 | 142 | 97 | 91 | 89 | 90 |
| Example 2 | 96 | 98 | 96 | 93 | 98 |
| Example 3 | 84 | 100 | 95 | 95 | 100 |
| Example 4 | 63 | 100 | 100 | 89 | 95 |
| Example 5 | 79 | 100 | 100 | 100 | 110 |
| Example 6 | 79 | 100 | 105 | 107 | 115 |
| Example 7 | 81 | 91 | 81 | 72 | 86 |
| Example 8 | 54 | 95 | 91 | 82 | 88 |
| Comparative | 126 | 98 | 87 | 83 | 90 |
| Example 1 | | | | | |
| Comparative | 103 | 97 | 94 | 88 | 94 |
| Example 2 | | | | | |
| Comparative | 123 | 98 | 92 | 89 | 96 |
| Example 3 | | | | | |
| Comparative | 96 | 97 | 74 | 56 | 75 |
| Example 6 | | | | | |

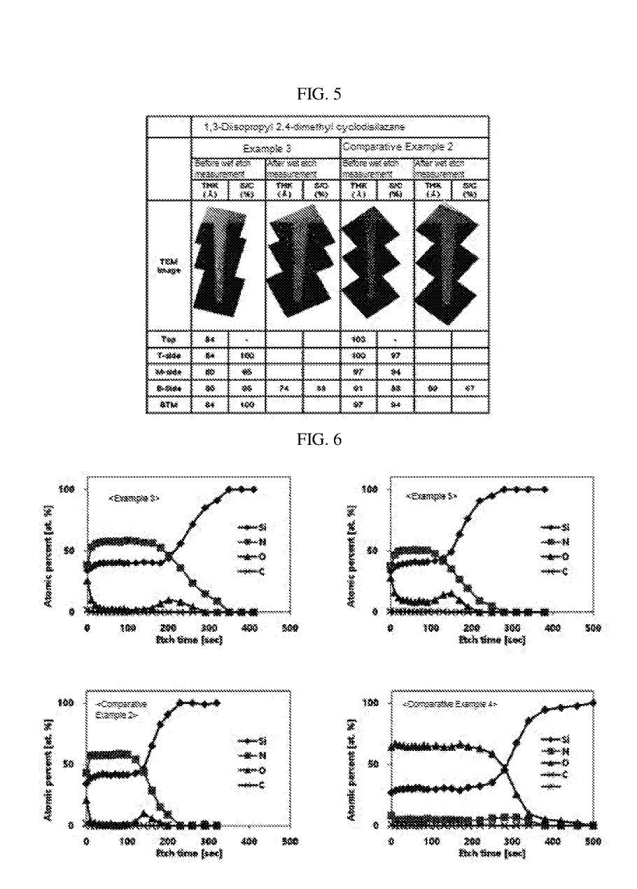

Deposition was performed using a patterned wafer having a space size of 75 nm and an aspect ratio of 6:1 (see FIGS. 4 and 5).

As shown in Table 4, in Examples according to the present invention, it was confirmed that thin films having a uniform thickness were formed regardless the depth as compared to Comparative Examples, and thus it was possible to have characteristics of the uniform thin film.

TABLE 5

| | Atomic composition ratio | | | |
|---|---|---|---|---|
| | | Oxygen | Carbon | |
| | Si/N Ratio | (atom %) | (atom %) | H content (%) |
| Example 3 | 0.70 | 1.7 | 0.00 | 6.86 |
| Example 4 | 0.70 | 2.2 | 0.00 | 8.40 |
| Example 5 | 0.80 | 8.31 | 0.37 | 22.70 |
| Example 6 | 0.79 | 5.2 | 0.00 | 25.98 |
| Example 7 | 0.75 | 2.80 | 0.00 | 6.83 |
| Example 8 | 0.74 | 4.20 | 0.00 | 7.90 |
| Comparative | 0.71 | 1.30 | 0.00 | 4.00 |
| Example 2 | | | | |
| Comparative | 0.77 | 3.60 | 0.00 | 5.10 |
| Example 3 | | | | |
| Comparative | 6.09 | 64.86 | 0.21 | 43.92 |
| Example 4 | | | | |
| Comparative | 5.89 | 64.63 | 0.21 | 45.00 |
| Example 5 | | | | |
| Comparative | 0.72 | 2.30 | 0.00 | 3.20 |
| Example 6 | | | | |

As shown in Table 5, it was confirmed that in Examples of the present invention, the silicon nitride thin film including a low content of oxygen and carbon could be formed. In addition, it was confirmed that in Examples 5 and 6, the porous thin films were formed by a relatively low substrate temperature to have high hydrogen and oxygen contents, but it was possible to form the silicon nitride thin film satisfying the desired composition ratio.

However, it was confirmed that in Comparative Examples 4 and 5 in which the porous thin films were formed in the same manner, it was difficult to form the subsequent silicon-nitrogen bond, and thus the silicon/nitrogen ratio (Si/N ratio) was significantly high, and the oxidation by atmospheric exposure after the process was rapid. Thus, the oxygen content was remarkably higher than that of Example 5 or 6.

In other words, according to the present invention, it is possible to form a silicon nitride thin film having excellent quality despite the low-temperature process conditions. In addition, the content of impurities in the silicon nitride thin film may be minimized and the high-purity silicon-nitride bond may be included, and thus a high quality silicon nitride thin film having excellent etch resistance may be formed and excellent step coverage characteristics may be exhibited to have high utilization value.

It will be appreciated by those skilled in the art that a number of and various modifications may be made without departing from the spirit of the invention. Therefore, it should be clearly understood that the above-described embodiments of the present invention are merely illustrative and are not intended to limit the scope of the invention.

1. A method for manufacturing a silicon nitride thin film using plasma atomic layer deposition by performing a unit cycle at least once comprising:
adsorbing an organic silicon precursor including a silicon-nitrogen bond on a substrate; and
exciting a first plasma while injecting a first reaction gas and then exciting a second plasma while injecting a second reaction gas to provide one or more reactive sites.

2. The method of claim 1, wherein the first reaction gas is a mixture of a nitrogen gas and a hydrogenation gas.

3. The method of claim 2, wherein the hydrogenation gas is selected from the group consisting of hydrogen, ammonia, and hydrazine.

4. The method of claim 3, wherein the first reaction gas is a mixture of the nitrogen gas and the hydrogenation gas at a flow ratio of 300:1 to 1:1.

5. The method of claim 1, wherein the second reaction gas is a nitrogen gas.

6. The method of claim 1, wherein the first plasma and the second plasma are excited with a power of 500 W or less.

7. The method of claim 6, wherein a temperature of the substrate ranges from 50° C. to 400° C.

8. The method of claim 1, wherein the organic silicon precursor including a silicon-nitrogen bond is selected from compounds represented by Chemical Formulas 1, 2, and 3 below: 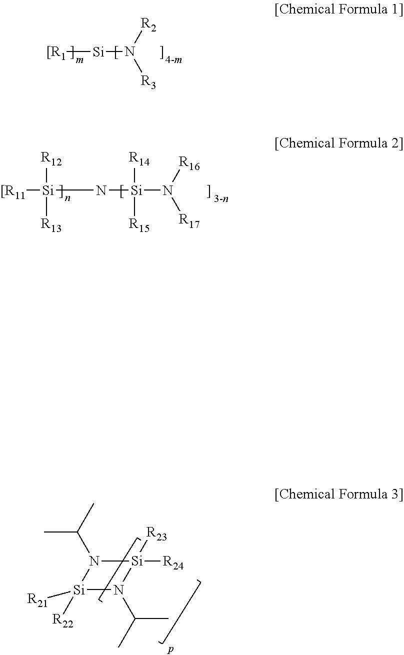
in Chemical Formulas 1, 2, and 3,
R₁ to R₃, R₁₁ to R₁₇, and R₂₁ to R₂₄ are each independently hydrogen, (C1-C5)alkyl, or (C2-C5)alkenyl;
n and m are each independently an integer of 0 to 3, and
p is an integer of 1 to 3.

9. The method of claim 8, wherein the organic silicon precursor including a silicon-nitrogen bond is selected from the following structures:

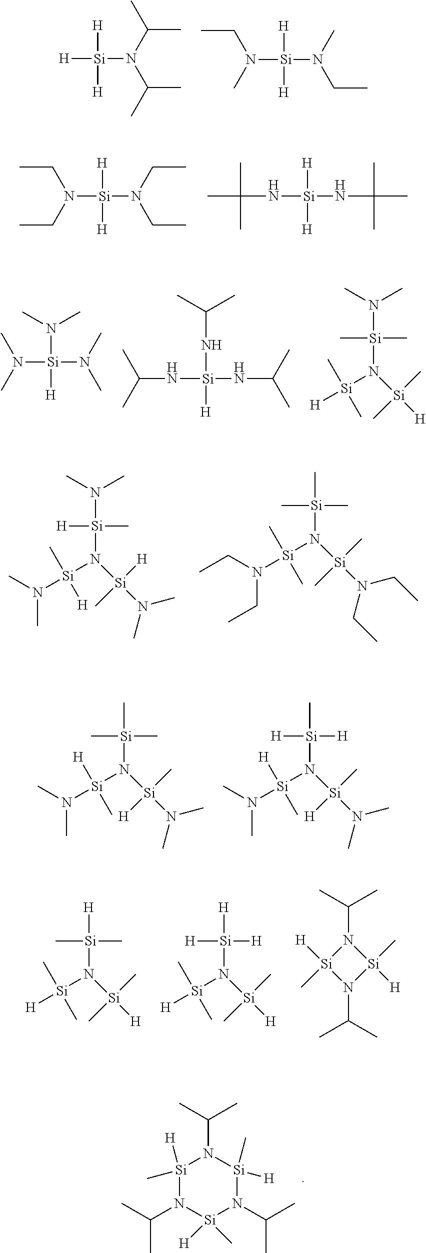

10. The method of claim 1, wherein the silicon nitride thin film has an oxygen element content of 10 atom % or less.

11. The method of claim 10, wherein the silicon nitride thin film has a silicon-nitrogen/silicon-hydrogen area ratio (Si—N/Si—H) of 90 or more.

12. A silicon nitride thin film in which an oxygen element content is 10 atom % or less and a silicon-nitrogen/silicon-hydrogen area ratio (Si—N/Si—H) is 90 or more.

13. The silicon nitride thin film of claim 12, wherein the silicon nitride thin film has a step coverage of 80% or more.
